(19) United States
(12) Patent Application Publication
(10) Pub. No.: US 2017/0067143 A1
(43) Pub. Date: Mar. 9, 2017

(54) METHOD OF MANUFACTURING PIEZOELECTRIC ELEMENT

(71) Applicant: SEIKO EPSON CORPORATION, Tokyo (JP)

(72) Inventors: Masao NAKAYAMA, Shiojiri-Shi (JP); Eiju HIRAI, Azumino-shi (JP); Toshihiro SHIMIZU, Suwa-gun (JP); Motoki TAKABE, Shiojiri-Shi (JP); Eiji OSAWA, Suwa-shi (JP)

(73) Assignee: SEIKO EPSON CORPORATION, Tokyo (JP)

(21) Appl. No.: 15/258,475

(22) Filed: Sep. 7, 2016

(30) Foreign Application Priority Data
Sep. 9, 2015 (JP) 2015-177846

(51) Int. Cl. C23C 14/18; H01L 41/277; B41J 2/16; C23C 14/58; C22F 1/14; C22F 1/18; H01L 41/29; C23C 14/34

(52) U.S. Cl. CPC C23C 14/185; H01L 41/29; H01L 41/277; C23C 14/3414; C23C 14/5806; C22F 1/14; C22F 1/183; B41J 2/1646; B41J 2/1607

(57) ABSTRACT

A method of manufacturing a piezoelectric element provided with first electrodes, a piezoelectric body layer, and a second electrode including a first platinum layer and second platinum layer, in which the first platinum layer having compression stress is formed on the piezoelectric body layer, which is provided on the first electrodes, using a sputtering technique, and the second platinum layer having tensile stress, is formed on the first platinum layer using a sputtering technique with a lower sputtering power than that when the first platinum layer is formed.

### BACKGROUND

1. Technical Field

The present invention relates to a method of manufacturing a piezoelectric element.

2. Related Art

A liquid ejecting head that ejects liquid droplets from a nozzle opening, which is in communication with a pressure generation chamber, by deforming a piezoelectric element and bringing about a pressure fluctuation in a liquid inside the pressure generation chamber, is known. An ink jet type recording head that ejects ink droplets, as liquid droplets, is a representative example of a liquid ejecting head. For example, an ink jet type recording head is provided with piezoelectric elements on one surface side of a flow channel formation substrate, in which pressure generation chambers that are in communication with nozzle openings, are provided, and ejects ink droplets from nozzle openings by bringing about pressure changes in ink inside the pressure generation chambers as a result of deforming a vibration plate due to driving of the piezoelectric elements.

The piezoelectric elements are provided with first electrodes (individual electrodes) that are respectively provided for the pressure generation chambers, a piezoelectric body layer that is provided throughout an area above each first electrode, and a second electrode (a common electrode) that is provided on the piezoelectric body layer, on a substrate. The second electrode is formed by stacking a plurality of layers formed of any one substance selected from the group consisting of iridium, platinum and palladium with the aim of suppressing a reduction in the properties of the piezoelectric elements, and the like (for example, refer to JP-A-2009-196329).

However, in a case in which iridium or palladium is used, a leakage current between the first electrodes and the second electrode is large since a work function is small, there is a concern that the piezoelectric body layer will fracture, and therefore, there is a problem with reliability.

In addition, in a case in which an ink jet type recording head is caused to perform high-speed character printing, it is necessary to increase the size of liquid droplets, but in order to discharge large liquid droplets, it is also necessary to increase driving voltages that are applied to piezoelectric elements. When the driving voltages are increased, there is a problem in that the reliability of the piezoelectric elements decreases.

The use of platinum has been considered in order to solve the above-mentioned problem. Since platinum has the largest work function, and the Schottky barrier thereof is high, it is possible to suppress a leakage current. However, there is a problem in that it is easy for platinum to peel away from the piezoelectric body layer.

### SUMMARY

An advantage of some aspects of the invention is that a method of manufacturing a piezoelectric element is provided in which reliability is improved by suppressing a leakage current and peeling of the electrode.

According to an aspect of the invention, there is provided a method of manufacturing a piezoelectric element, which is provided with first electrodes, a piezoelectric body layer, and a second electrode including a first platinum layer and second platinum layer, in which the first electrodes are individual electrodes that are respectively provided in an electrically independent manner for active sections, and the second electrode is a common electrode that is provided in an electrically common manner throughout the active sections, the method including: forming the first platinum layer having compression stress or tensile stress on the piezoelectric body layer, which is provided on the first electrodes, using a sputtering technique; and forming the second platinum layer having tensile stress or compression stress, on the first platinum layer using a sputtering technique with a sputtering power that differs from that during the formation of the first platinum layer.

In this case, it is possible to form a piezoelectric element having a high reliability in which a leakage current is suppressed, and fracturing is prevented by using the first layer that is formed of the first platinum layer and the second platinum layer. Further, it is possible to form a first layer in which peeling and fracturing are suppressed as a result of stress being alleviated by forming a first platinum layer and a second platinum layer with different sputtering powers, and therefore, it is possible to manufacture a piezoelectric element having a high reliability.

In addition, it is preferable that the method include forming the first platinum layer having compression stress on the piezoelectric body layer using a sputtering technique, and forming the second platinum layer having tensile stress on the first platinum layer using a sputtering technique with a sputtering power that is lower than that during formation of the first platinum layer. In this case, the adhesive properties of the first platinum layer with respect to the piezoelectric body layer are further improved, and therefore, it is possible to manufacture a piezoelectric element having even higher reliability.

In addition, it is preferable that a titanium layer be formed on the second platinum layer. In this case, the adhesive properties of the first layer and the second layer are improved, and therefore, it is possible to manufacture a piezoelectric element having a high reliability.

In addition, it is preferable that heat treatment be performed after formation of the second platinum layer. In this case, excess lead that is included in the piezoelectric body layer is absorbed into the titanium layer, and therefore, it is possible to form a highly reliable piezoelectric element.

In addition, it is preferable that the second electrode include a second layer that is provided on a first layer formed of the first platinum layer and the second platinum layer, and that the second layer cover an outer surface of the first layer and a side surface of the piezoelectric body layer. In this case, it is possible to reliably cause the first layer and the piezoelectric body layer to adhere to one another using the second layer.

In addition, it is preferable that the second layer, which includes at least one metal selected from a group consisting of iridium, nickel, tungsten, aluminum, nichrome, gold and titanium, be formed. In this case, it is possible to reliably cause the first layer and the piezoelectric body layer to ahere to one another using the second layer.

### BRIEF DESCRIPTION OF THE DRAWINGS

The invention will be described with reference to the accompanying drawings, wherein like numbers reference like elements.

FIG. 1 is a perspective view of an ink jet type recording head.

FIG. 2 is a plan view of a flow channel formation substrate of the ink jet type recording head.

FIG. 3 is a cross-sectional view that follows a line III-III in FIG. 2.

FIG. 4 is a cross-sectional view in which a portion of FIG. 3 is enlarged.

FIG. 5 is a cross-sectional view that follows a line V-V in FIG. 3.

FIG. 6 is a cross-sectional view in which a portion of FIG. 5 is enlarged.

FIG. 7 is a cross-sectional view that shows a method of manufacturing a piezoelectric element.

FIG. 8 is a cross-sectional view that shows the method of manufacturing a piezoelectric element.

FIG. 9 is a cross-sectional view that shows the method of manufacturing a piezoelectric element.

FIG. 10 is a cross-sectional view that shows the method of manufacturing a piezoelectric element.

FIG. 11 is a cross-sectional view that shows the method of manufacturing a piezoelectric element.

FIG. 12 is a cross-sectional view that shows the method of manufacturing a piezoelectric element.

FIG. 13 is a cross-sectional view that shows the method of manufacturing a piezoelectric element.

FIG. 14 is a cross-sectional view that shows the method of manufacturing a piezoelectric element.

FIG. 15 is a cross-sectional view that shows the method of manufacturing a piezoelectric element.

FIG. 16 is a cross-sectional view that shows the method of manufacturing a piezoelectric element.

FIG. 17 is a cross-sectional view that shows the method of manufacturing a piezoelectric element.

FIG. 18 is a cross-sectional view that shows the method of manufacturing a piezoelectric element.

FIG. 19 is a cross-sectional view that shows the method of manufacturing a piezoelectric element.

FIG. 20 is a cross-sectional view that shows the method of manufacturing a piezoelectric element.

FIG. 21 is a schematic perspective view that shows an example of an ink jet type recording apparatus.

### DESCRIPTION OF EXEMPLARY EMBODIMENTS

### Embodiment 1

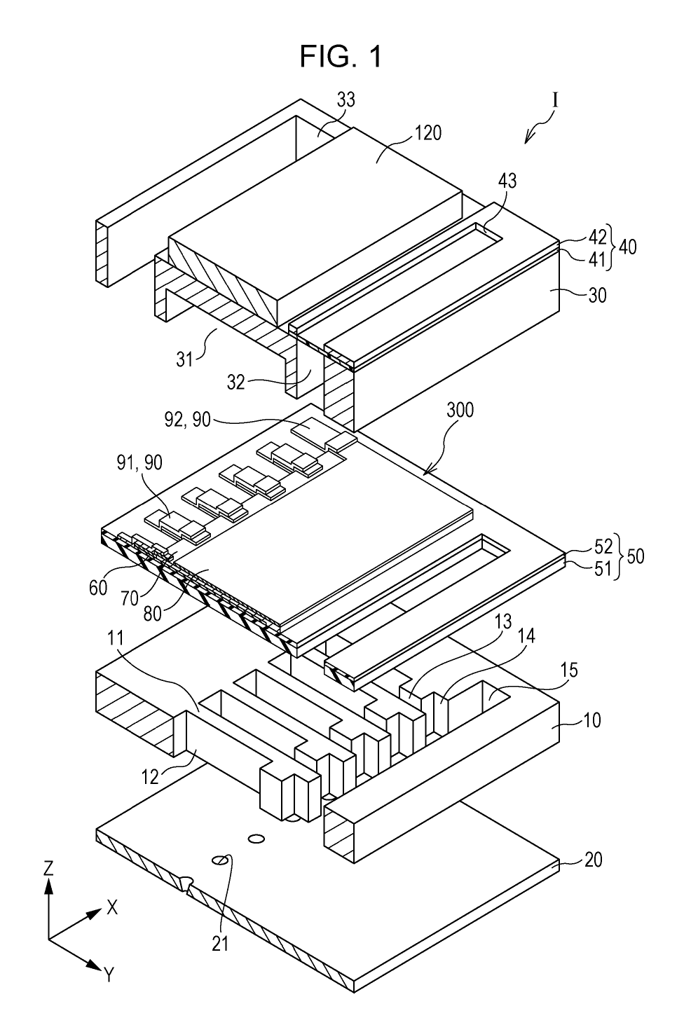

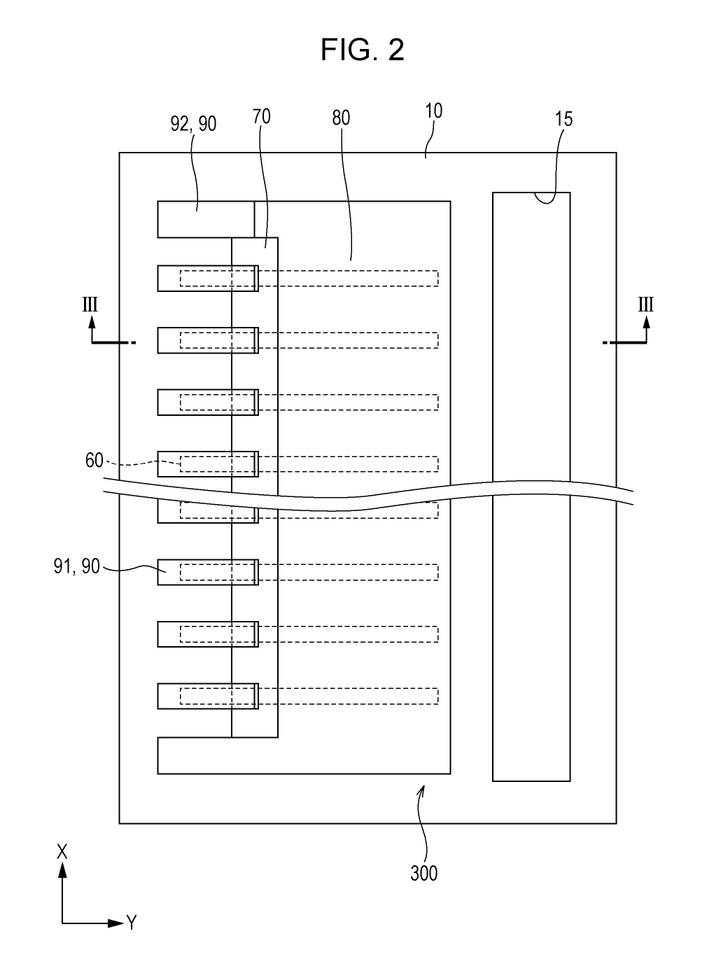

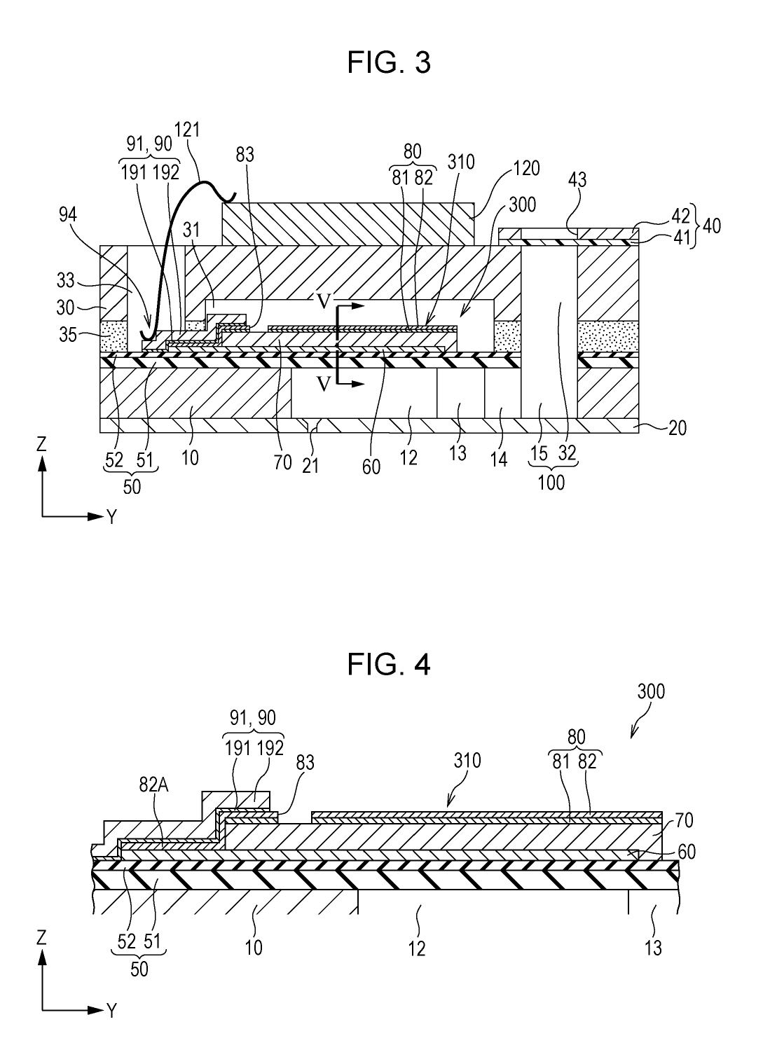

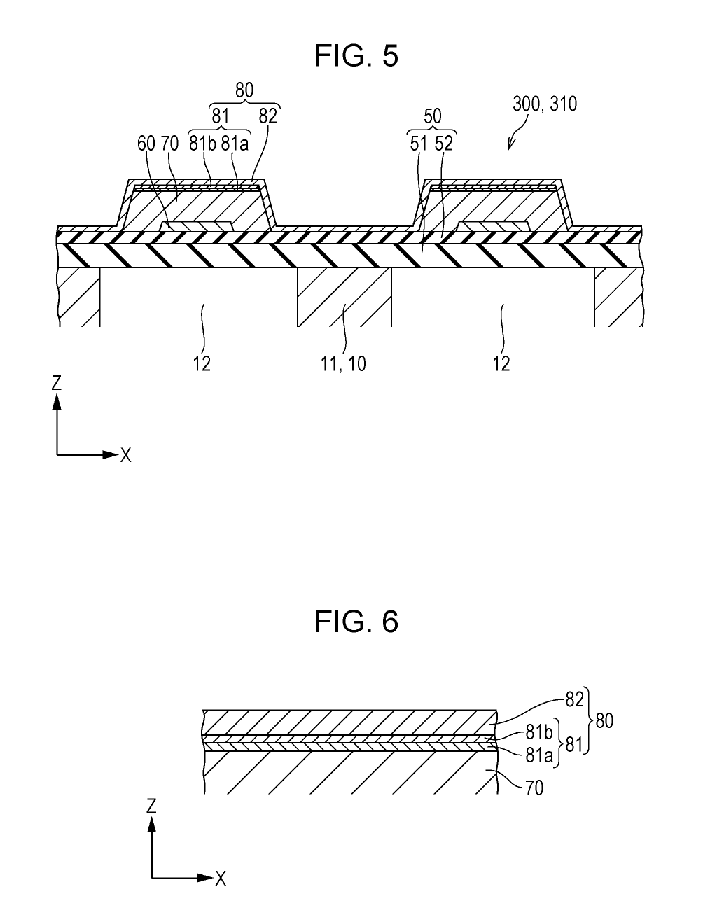

FIG. 1 is a perspective view of an ink jet type recording head, which is an example of a liquid ejecting head according to Embodiment 1 of the invention, FIG. 2 is a plan view of a flow channel formation substrate of the ink jet type recording head, FIG. 3 is a cross-sectional view that follows a line III-III in FIG. 2, FIG. 4 is a cross-sectional view in which a portion of FIG. 3 is enlarged, FIG. 5 is a cross-sectional view that follows a line V-V in FIG. 3, and FIG. 6 is a cross-sectional view in which a portion of FIG. 5 is enlarged.

Pressure generation chambers 12, which are partitioned by a plurality of dividing walls 11, are formed in a flow channel formation substrate 10, which is a substrate provided with an ink jet type recording head I. The pressure generation chambers 12 are arranged in parallel along a direction in which a plurality of nozzle openings 21, which discharge ink of the same color, are arranged side by side. Hereinafter, this direction will be referred to as a parallel arrangement direction of the pressure generation chambers 12 or as a first direction X. In addition, hereinafter, a direction that is orthogonal to the first direction X will be referred to as a second direction Y. Furthermore, hereinafter, a direction that is orthogonal to both the first direction X and the second direction Y will be referred to as a third direction Z.

In addition, ink supply channels 13 and communication channels 14 are partitioned by the plurality of dividing walls 11 on one end portion side of the flow channel formation substrate 10 in a longitudinal direction of the pressure generation chambers 12, that is, on one end portion side in the second direction Y. A communication section 15 that forms a portion of a manifold 100, which corresponds to an ink chamber (liquid chamber) that is common to each of the pressure generation chambers 12, is formed on an outer side of the communication channels 14 (on a side that is opposite to the pressure generation chambers 12 in the second direction Y). That is, a liquid flow channel that is formed from the pressure generation chambers 12, the ink supply channels 13, the communication channels 14 and the communication section 15 is provided in the flow channel formation substrate 10.

A nozzle plate 20, in which the nozzle openings 21 that are in communication with corresponding ones of the pressure generation chambers 12 are machined, is bonded to one surface side of the flow channel formation substrate 10, that is, a surface on which the liquid flow channel of the pressure generation chambers 12, and the like is open, using an adhesive agent, a heat welding film, or the like. That is, the nozzle openings 21 are arranged side by side on the nozzle plate 20 in the first direction X.

A vibration plate 50 is formed on the other surface side of the flow channel formation substrate 10. The vibration plate 50 according to the present embodiment is formed of an elastic film 51 that is formed on the flow channel formation substrate 10, and an insulating body film 52 that is formed on the elastic film 51. Additionally, the liquid flow channel of the pressure generation chambers 12 and the like, is formed by performing anisotropic etching of the flow channel formation substrate 10 from one surface, and the other surface of the liquid flow channel of the pressure generation chambers 12 and the like, is formed of the vibration plate 50 (the elastic film 51).

A piezoelectric element 300, which is formed of first electrodes 60, a piezoelectric body layer 70 and a second electrode 80, is formed on the insulating body film 52. In the present embodiment, the flow channel formation substrate 10, in which the pressure generation chambers 12 are formed, the vibration plate 50 and the piezoelectric element 300 correspond to an actuator device, which is an example of a piezoelectric device that is provided with a piezoelectric element.

The first electrodes 60 that form the piezoelectric element 300 of the present embodiment are divided among the pressure generation chambers 12, and form individual electrodes that are independently provided for active sections 310, which will be described later. The first electrodes 60 are each formed with a width that is narrower than the width of each of the pressure generation chambers 12 in the first direction X of the pressure generation chambers. That is, in the first direction X of the pressure generation chambers 12, the first electrodes 60 are positioned on inner sides of regions that face the pressure generation chambers 12. In addition, both end portions of the first electrodes 60 in the second direction Y respectively extend up to outer sides of the pressure generation chambers 12. Additionally, the material of the first electrodes 60 is preferably a material that can retain conductivity without becoming oxidized during film formation of the piezoelectric body layer 70, which will be described later, and for example, a precious metal such as platinum (Pt) or iridium (Ir), or a conductive oxide of which lanthanum nickel oxide (LNO) is representative is suitably used.

An adhesive layer for ensuring adhesive force may be used between the abovementioned conductive material, as the first electrodes 60, and the vibration plate 50. In the present embodiment, although not specifically illustrated in the drawings, titanium is used as the adhesive layer. Additionally, it is possible to use zirconium, titanium, titanium oxide or the like, as the adhesive layer. That is, in the present embodiment, the first electrodes 60 are formed of an adhesive layer that is composed of titanium and a conductive layer of at least one material selected from the above-mentioned conductive materials.

The piezoelectric body layer 70 is provided continuously in the first direction X so as to have a predetermined width in the second direction Y. The width of the piezoelectric body layer 70 in the second direction Y is greater than the length of the pressure generation chambers 12 in the second direction Y. Therefore, the piezoelectric body layer 70 is provided up to an outer side of the pressure generation chambers 12 in the second direction Y of the pressure generation chambers 12.

In the second direction Y of the pressure generation chambers 12, the end portion of the piezoelectric body layer 70 on the ink supply channel 13 side is positioned further toward an outer side than corresponding end portions of the first electrodes 60. That is, end portions of the first electrodes 60 are covered by the piezoelectric body layer 70. In addition, the end portion of the piezoelectric body layer 70 on the nozzle openings 21 side is positioned further toward an inner side (the pressure generation chambers 12 side) than corresponding end portions of the first electrodes 60, and the end portions of the first electrodes 60 on the nozzle openings 21 side are not covered by the piezoelectric body layer 70.

The piezoelectric body layer 70 is a perovskite structure crystalline film (a perovskite type crystal) that is formed of a ferroelectric ceramic material that exhibits an electromechanical conversion effect. For example, it is possible to use a ferroelectric piezoelectric material such as lead zirconate titanate (PZT), a material in which a metal oxide such as niobium oxide, nickel oxide or magnesium oxide is added to a ferroelectric piezoelectric material, or the like, as the material of the piezoelectric body layer 70. In addition, the material of the piezoelectric body layer 70 is not limited to a lead-based piezoelectric material, which includes lead, and it is also possible to use a non-lead-based material, which does not include lead.

Although this will be described in more detail later, the piezoelectric body layer 70 can be formed by a liquid phase technique such as a sol-gel technique or a metal-organic decomposition (MOD) technique, or a physical vapor deposition (PVD) technique (a gas phase technique) such as a sputtering technique or a laser ablation technique, or the like.

The second electrode 80 is provided on a surface side of the piezoelectric body layer 70 that is opposite to the first electrodes 60, and forms a common electrode that is common to the active sections 310. In the present embodiment, the second electrode 80 is provided with a first layer 81, which is provided on the piezoelectric body layer 70 side, and a second layer 82, which is provided on a side of the first layer 81 that is opposite to the piezoelectric body layer 70.

The first layer 81 is formed from platinum (Pt). Furthermore, the first layer 81 is a layer in which a first platinum layer 81a and a second platinum layer 81b are stacked.

The first platinum layer 81a is a layer that is formed from platinum, which is formed on the piezoelectric body layer 70 side of the first layer 81. Although described in more detail later, the first platinum layer 81a is formed using a sputtering technique, and for example, has a film thickness of approximately 2.5 nm.

The second platinum layer 81b is a layer that is formed from platinum, which is formed on the second layer 82 side of the first layer 81. Although described in more detail later, the second platinum layer 81b is formed using a sputtering technique, and for example, has a film thickness of approximately 2.5 nm.

The first platinum layer 81a and the second platinum layer 81b are both formed using sputtering techniques, but the sputtering powers (the electric power that is supplied to a target that includes platinum in the sputtering techniques) thereof differ. In the present embodiment, the sputtering power that is applied at the time of forming the second platinum layer 81b using a sputtering technique, is lower than the sputtering power that is applied at the time of forming the first platinum layer 81a using a sputtering technique. The first platinum layer 81a, which is formed using a relatively high sputtering power, has favorable adhesive properties with respect to the piezoelectric body layer 70.

Furthermore, since the first platinum layer 81a is formed using a relatively high sputtering power, the first platinum layer 81a has compression stress. On the other hand, since the second platinum layer 81b is formed using a relatively low sputtering power, the second platinum layer 81b has tensile stress. Since the first platinum layer 81a and the second platinum layer 81b, which differ in this manner and have compression stress and tensile stress, are stacked together, the respective compression stress and tensile stress are alleviated. As a result of the stresses being alleviated in this manner, the adhesive properties of the first layer 81, which is formed from the first platinum layer 81a and the second platinum layer 81b, with respect to the piezoelectric body layer 70, are improved. In addition, since the first platinum layer 81a and the second platinum layer 81b are made from the same metal, the adhesive properties thereof are also high.

In this manner, as a result of being provided with the first layer 81 that is formed of the first platinum layer 81a and the second platinum layer 81b, a leakage current is suppressed, and therefore, the piezoelectric element 300 is a piezoelectric element having high reliability in which fracturing of the piezoelectric body layer 70 is suppressed. Further, as a result of being provided with the first platinum layer 81a and the second platinum layer 81b, which are formed using sputtering techniques with different sputtering powers, stress is alleviated, and therefore, the piezoelectric element 300 is a piezoelectric element having high reliability in which peeling and fracturing of the first layer 81 is suppressed.

Additionally, forming the first platinum layer 81a only as the first layer 81 using a sputtering technique can also be considered. In this case, since the compression stress of the first platinum layer 81a is not alleviated, there is a concern that the first platinum layer 81a will peel away or fracture due to the compression stress. Even in a case in which the first platinum layer 81a is formed using a sputtering technique with a low sputtering power, since tensile stress is generated in the first platinum layer 81a, and the tensile stress is not alleviated, there is a concern that the first platinum layer 81a will peel away or fracture.

It is preferable that the second layer 82 is a metal having a strong adhesive force and low resistance with respect to platinum and the piezoelectric body layer. More specifically, it is preferable that at least one metal selected from the group consisting of iridium, nickel, tungsten, aluminum, nichrome, gold and titanium, be used. In addition, a titanium layer, which is formed from titanium, may be provided between the first layer 81 and the second layer 82, that is, on the second platinum layer 81b. In the present embodiment, a multi-layer electrode of iridium (Ir) and titanium (Ti) is used as the second layer 82.

The first layer 81 is formed on the piezoelectric body layer 70 only, that is, only on the outer surface of a side of the piezoelectric body layer 70 that is opposite to the flow channel formation substrate 10. In addition, in the present embodiment, the second layer 82 is continuously provided throughout an area on the first layer 81, on a side surface of the piezoelectric body layer 70 on which the first layer 81 is not provided, and on the first electrode 60.

The second layer 82 on the first layer 81 and the second layer 82 on the first electrode 60 are disconnected electrically by a removed section 83. That is, the second layer 82 on the first layer 81 and the second layer 82 on the first electrode 60 are formed from the same layer, but are formed in an electrically discontinuous manner. In this instance, the removed section 83 is provided on the nozzle openings 21 side on the piezoelectric body layer 70, and is a section that disconnects both the first layer 81 and the second layer 82 electrically by penetrating therethrough in the thickness direction. The removed section 83 of this type is provided penetrating through the second electrode 80 in the thickness direction thereof in a continuous manner in the first direction X.

Displacement occurs in the piezoelectric element 300 as a result of a voltage being applied between each of the first electrodes 60 and the second electrode 80. That is, piezoelectric strain occurs in the piezoelectric body layer 70, which is interposed between each of the first electrodes 60 and the second electrode 80 as a result of a voltage being applied between the electrodes 60 and 80. Further, when a voltage is applied between the electrodes 60 and 80, a portion in which a piezoelectric distortion occurs in the piezoelectric body layer 70 is referred to as the active section 310. In contrast to this, portions in which a piezoelectric distortion does not occur in the piezoelectric body layer 70 are referred to as non-active portions. An end portion of the active section 310 in the first direction X is defined by the first electrodes 60. In addition, an end portion of the active section 310 in the second direction Y is defined by the second electrode 80 (the removed section 83).

Individual lead electrodes 91 and a common lead electrode 92 are connected to the first electrodes 60 and the second electrode 80 of the piezoelectric element 300.

In the present embodiment, the individual lead electrodes 91 and the common lead electrode 92 (hereinafter, collectively referred to as lead electrodes 90) are formed from the same layer, but are formed in an electrically discontinuous manner. More specifically, the lead electrodes 90 are provided with an adhesive layer 191, which is provided on an electrode (the second layer 82 of the second electrode 80) side, and a conductive layer 192, which is provided on the adhesive layer 191.

The adhesive layer 191 is a layer for improving the adhesive properties between the second layer 82, the vibration plate 50 and the like, and the conductive layer 192, and it is possible to use nickel (Ni), chromium (Cr), nickel chromium (NiCr), titanium (Ti), titanium tungsten (TiW) or the like, as the material thereof. Naturally, the adhesive layer 191 may also be a layer that uses a single material from among the above-mentioned substances, or alternatively, may be a complex material in which a plurality of materials are mixed, or further, may be a layer in which a plurality of layers of different materials are stacked together. In the present embodiment, nickel chromium (NiCr) is used as the adhesive layer 191.

In addition, the conductive layer 192 is not particularly limited as long as it is a material with comparatively high conductivity; for example, it is possible to use gold (Au), platinum (Pt), aluminum (Al), copper (Cu), or the like. In the present embodiment, gold (Au) is used as the conductive layer 192.

The individual lead electrodes 91 are respectively provided on the first electrodes 60, which are provided on the outer side of the piezoelectric body layer 70. Although formed from the same layer as the second layer 82 of the second electrode 80, an electrode layer 82A, which is discontinuous with the second layer 82, is provided on the first electrodes 60. Therefore, the first electrodes 60 and the individual lead electrodes 91 are electrically connected through the electrode layer 82A.

The common lead electrode 92 is provided on the second electrode 80 (on the second electrode 80 of the piezoelectric body layer 70). As shown in FIGS. 1 and 2, the common lead electrode 92 of this kind is continuously drawn out onto the vibration plate 50 in the second direction Y to both end portions of the flow channel formation substrate 10 in the first direction X.

A protective substrate 30, which protects the piezoelectric element 300, is joined onto the flow channel formation substrate 10, on which the piezoelectric element 300 of this type is formed, using an adhesive 35. A piezoelectric element retention portion 31, which is a concave section that defines a space in which the piezoelectric element 300 is accommodated, is provided in the protective substrate 30. In addition, a manifold portion 32, which forms a portion of the manifold 100, is provided in the protective substrate 30. The manifold portion 32 is formed over the entirety of a width direction of the pressure generation chambers 12 penetrating the protective substrate 30 in the thickness direction, and in the above-mentioned manner, is continuous with the communication section 15 of the flow channel formation substrate 10. In addition, a through hole 33, which penetrates the protective substrate 30 in the thickness direction, is provided in the protective substrate 30. The lead electrodes 90 (the individual lead electrodes 91), which are connected to the first electrodes 60 of the active sections 310, and the lead electrode 90 (the common lead electrode 92), which is connected to the second electrode 80, are exposed inside the through hole 33, and one end of connection wiring, which is connected to a driving circuit, which is not illustrated in the drawings, is connected to the lead electrodes 90 inside the through hole 33.

A compliance substrate 40, which is formed from a sealing film 41 and a fixing plate 42 is joined onto the protective substrate 30. The sealing film 41 is formed from a material having low rigidity and a flexible property, and a surface of the manifold portion 32 is sealed using the sealing film 41. In addition, the fixing plate 42 is formed with a hard material such as a metal. Since a region of the fixing plate 42 that faces the manifold 100 is an open portion 43 formed through complete removal in the thickness direction, the surface of the manifold 100 is sealed by only the sealing film 41, which is flexible.

In this kind of ink jet type recording head I of the present embodiment, ink is taken in from an ink introduction port, which is connected to an external ink supply unit, which is not illustrated in the drawings, an inner section from the manifold 100 to the nozzle openings 21 is filled with ink, and thereafter, voltages are respectively applied between the first electrodes 60 and the second electrode 80 that correspond to the pressure generation chambers 12 in accordance with a recording signal from the driving circuit. As a result of this, the piezoelectric element 300 and the vibration plate 50 are deformed in a deflection manner, pressure inside each of the pressure generation chambers 12 is increased, and ink droplets are ejected from each of the nozzle openings 21.

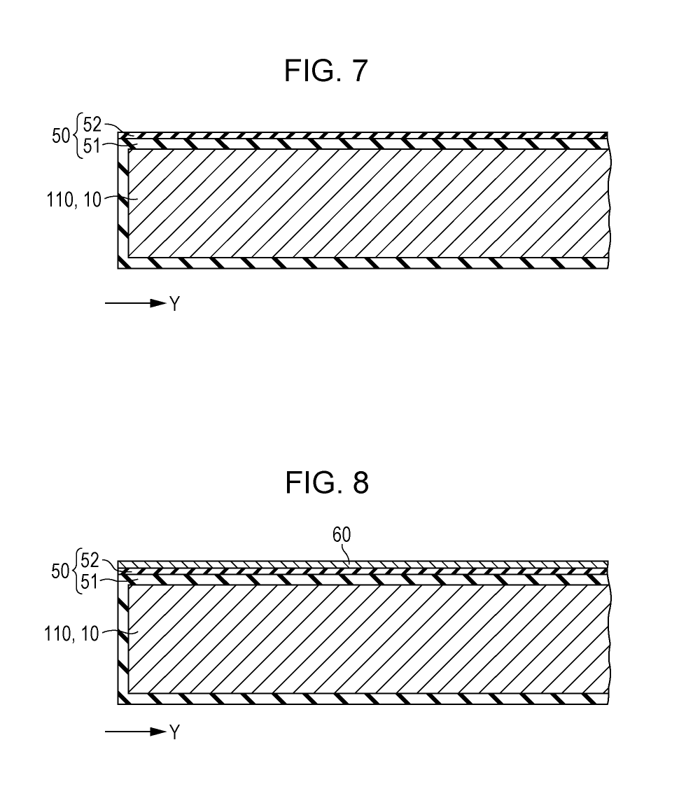

A method of manufacturing an ink jet type recording head, which includes the method of manufacturing a piezoelectric element of the present embodiment, will be described. Additionally, FIGS. 7 to 20 are cross-sectional views that show the method of manufacturing a piezoelectric element and an ink jet type recording head.

As shown in FIG. 7, the vibration plate 50 is formed on an outer surface of a flow channel formation substrate wafer 110, which is a silicon wafer on which the flow channel formation substrate is formed in a plurality and the plurality of the flow channel formation substrates 10 are formed integrally. In the present embodiment, the vibration plate 50, which is formed by stacking silicon dioxide (the elastic film 51), which is formed through thermal oxidation of the flow channel formation substrate wafer 110, and zirconium oxide (the insulating body film 52), which is formed through thermal oxidation after film formation using a sputtering technique, is formed.

Next, as shown in FIG. 8, each of the first electrodes 60 is formed over the entire surface of the insulating body film 52. The material of the first electrodes 60 is not particularly limited; for example, a metal such as platinum or iridium, in which conductivity does not become impaired at high temperatures, or a conductive oxide such as iridium oxide or lanthanum nickel oxide, or a multi-layer material formed of these materials is suitably used. In addition, the first electrodes 60 can be formed using a sputtering technique or a PVD method (a physical vapor deposition technique), gas phase film formation such as a laser ablation technique, liquid phase film formation such as a spin coating technique, or the like. In addition, an adhesive layer for ensuring adhesive force may be used between the above-mentioned conductive material and the vibration plate 50. In the present embodiment, although not specifically illustrated in the drawings, titanium is used as an adhesive layer. Alternatively, it is possible to use zirconium, titanium, titanium oxide or the like, as the adhesive layer. In addition, a control layer for controlling crystal growth of the piezoelectric body layer 70 may be formed on an electrode outer surface (a film formation side of the piezoelectric body layer 70). In the present embodiment, titanium is used for crystal control of the piezoelectric body layer 70 (PZT). Since titanium is taken into the inside of the piezoelectric body layer 70 during film formation of the piezoelectric body layer 70, the titanium is not present as a film after film formation of the piezoelectric body layer 70. A conductive oxide, or the like, having a perovskite type crystal structure such as lanthanum nickel oxide, may be used as a crystal control layer.

Next, in the present embodiment, the piezoelectric body layer 70, which is formed from lead zirconate titanate (PZT), is formed. The piezoelectric body layer 70 can be formed using a so-called sol-gel technique that obtains the piezoelectric body layer 70, which is formed from a metal oxide by gelatinization as a result of coating and drying a so-called sol, in which a metal complex is dissolved or dispersed in a solvent, and further firing the sol at a high temperature. Additionally, the method of manufacturing the piezoelectric body layer 70 is not limited to a sol-gel technique, and for example, a physical vapor deposition (PVD) technique such as a metal-organic decomposition (MOD) technique, a sputtering technique or a laser ablation technique may be used. That is, the piezoelectric body layer 70 may be formed using either a liquid or a gas phase technique.

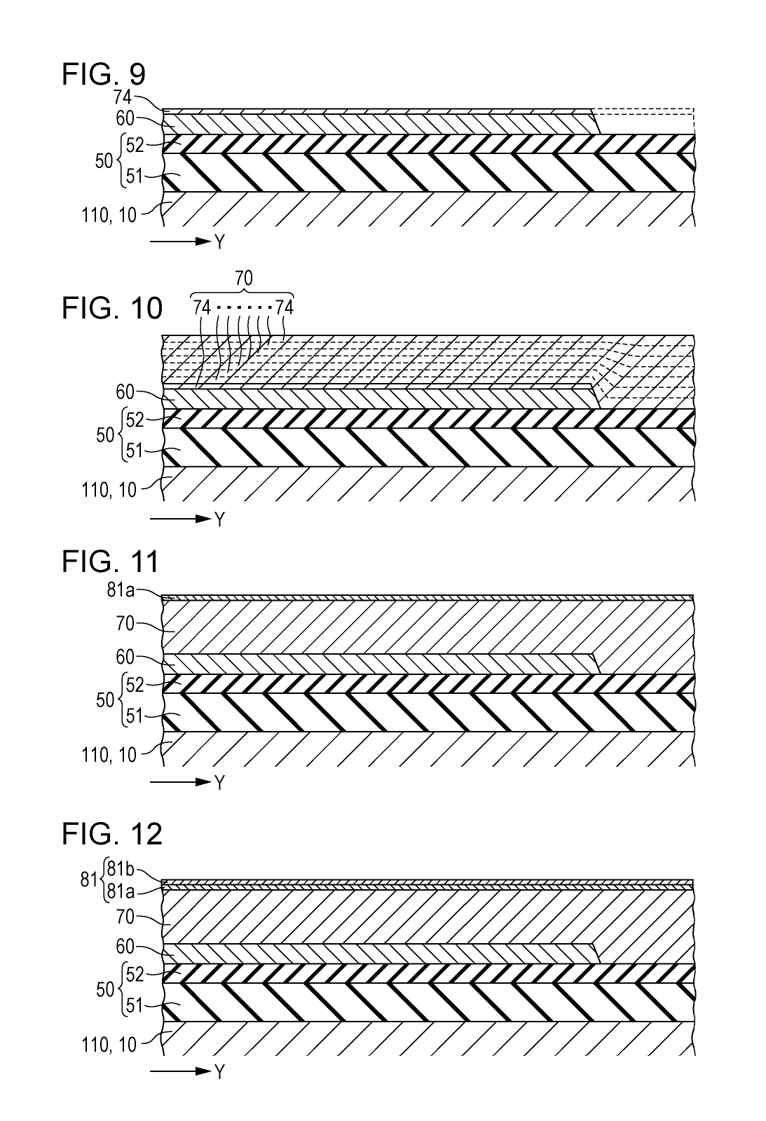

In the present embodiment, the piezoelectric body layer 70 is formed by stacking a plurality of layers of a piezoelectric body film 74. More specifically, as shown in FIG. 9, the first electrodes 60 and a first layer of the piezoelectric body film 74 are simultaneously patterned so that the side surfaces thereof are inclined using a step in which the first layer of the piezoelectric body film 74 is formed on the first electrodes 60. Additionally, the patterning of the first electrodes 60 and the first layer of the piezoelectric body film 74 can, for example, be performed using dry etching such as reactive ion etching (RIE), ion milling or the like.

In this instance, for example, in a case in which the first layer of the piezoelectric body film 74 is formed after patterning the first electrodes 60, since the first electrodes 60 are patterned using a photolithography process, ion milling or asking, the outer surface of the first electrodes 60, a crystal seed layer such as titanium that is provided on the outer surface but is not illustrated in the drawings, and the like, are transformed. When this occurs, even if the piezoelectric body film 74 is formed on the transformed surface, the crystallinity of the piezoelectric body film 74 is no longer favorable, and therefore, since crystal growth is carried out in a second layer and upwards of the piezoelectric body film 74 with an influence on the crystalline state of the first layer of the piezoelectric body film 74, it is not possible to form the piezoelectric body layer 70 that has favorable crystallinity.

In comparison to this, if patterning is performed simultaneously with the first electrodes 60 after formation of the first layer of the piezoelectric body film 74, the first layer of the piezoelectric body film 74 has a strong characteristic as a seed for favorably performing crystal growth of the second layer and upwards of the piezoelectric body film 74 in comparison with a crystal seed such as titanium, and even if an extremely thin transformed layer is formed on a surface layer by patterning, this does not have a large influence on the crystal growth of the second layer and upwards of the piezoelectric body film 74.

Additionally, when films of the second layer and upwards of the piezoelectric body film 74 are formed on the vibration plate 50 (the insulating body film 52, which is zirconium oxide in the present embodiment) which is exposed prior to formation of the second layer of the piezoelectric body film 74, a crystal control layer (an intermediate crystal control layer) may be used. In the present embodiment, titanium is used as the intermediate crystal control layer. The intermediate crystal control layer, which is formed from titanium, is taken into the piezoelectric body film 74 during film formation of the piezoelectric body film 74 in the same manner as the titanium of the crystal control layer that is formed on the first electrodes 60. In a case in which the intermediate crystal control layer is an intermediate electrode or a dielectric body of a capacitor, which is connected in series, the piezoelectric characteristics deteriorate. Therefore, it is desirable that the intermediate crystal control layer be taken into the piezoelectric body film 74 (the piezoelectric body layer 70) and does not remain as a film after film formation of the piezoelectric body layer 70.

Next, as shown in FIG. 10, the piezoelectric body layer 70, which is formed from a plurality of piezoelectric body films 74, is formed by performing stacking of the second layer and upwards of the piezoelectric body film 74. Incidentally, the second layer and upwards of the piezoelectric body film 74 are formed continuously throughout an area on the insulating body film 52, on the side surfaces of the first electrode 60 and the first layer of the piezoelectric body film 74, and on the first layer of the piezoelectric body film 74.

Next, the first layer 81, which forms the second electrode 80 is formed on the piezoelectric body layer 70. The first layer 81 is formed by forming the second platinum layer 81b after initially forming the first platinum layer 81a.

As shown in FIG. 11, the first platinum layer 81a is formed on the piezoelectric body layer 70. More specifically, a target that is formed from the flow channel formation substrate wafer 110 and platinum is disposed inside a chamber of a sputtering device. Further, the first platinum layer 81a is formed using a sputtering technique by introducing an inert gas inside the chamber, setting the flow channel formation substrate wafer 110 to a predetermined temperature, and supplying a sputtering power to the target.

The sputtering power is higher than a sputtering power at the time of forming the second platinum layer 81b. For example, the sputtering power is set to 31 kW/m². In addition, it is preferable that the temperature during film formation be approximately 250° C. to 330° C. In this instance, the first platinum layer 81a with a thickness of approximately 2.5 nm is formed under film formation conditions such as those mentioned above.

By forming the first platinum layer 81a with a relatively high sputtering power, it is possible to improve the adhesive properties of the first platinum layer 81a with respect to the piezoelectric body layer 70. In addition, since a relatively high sputtering power is applied, it is possible to form the first platinum layer 81a having compression stress.

In addition, although not specifically illustrated in the drawings, heat treatment may be carried out on the first platinum layer 81a after formation of the first platinum layer 81a. As a result of this heat treatment, damage to the first platinum layer 81a due to the sputtering technique can be repaired, and therefore, it is possible to form the piezoelectric element 300 having even higher reliability.

Next, as shown in FIG. 12, the second platinum layer 81b is formed on the first platinum layer 81a. More specifically, in the same manner as the first platinum layer 81a, the second platinum layer 81b is formed on the first platinum layer 81a with a sputtering technique using a sputtering device. As a result of forming the second platinum layer 81b on the first platinum layer 81a in this manner, the first layer 81, which includes the first platinum layer 81a and the second platinum layer 81b, is formed.

The sputtering power is lower than the sputtering power at the time of forming the first platinum layer 81a. In this instance, for example, the sputtering power is set to 9.3 kW/m². In addition, it is preferable that the temperature during film formation is approximately 250° C. to 330° C. In this instance, the second platinum layer 81b with a thickness of approximately 2.5 nm is formed with film formation conditions such as those mentioned above.

In this manner, since a relatively low sputtering power is applied, it is possible to form the second platinum layer 81b having tensile stress. That is, since the second platinum layer 81b, which has tensile stress, is stacked onto the first platinum layer 81a, which has compression stress, it is possible to alleviate the compression stress and the tensile stress. As a result of this, it is possible to form the first layer 81, which is formed from the first platinum layer 81a and the second platinum layer 81b, and in which the adhesive properties with respect to the piezoelectric body layer 70 are high.

Additionally, in the above-mentioned piezoelectric element 300, the first platinum layer 81a is formed using a relatively high sputtering power, and the second platinum layer 81b is formed using a relatively low sputtering power, but the opposite may also be performed. That is, the first platinum layer 81a may be formed using a relatively low sputtering power, and the second platinum layer 81b may be formed using a relatively high sputtering power. As a result of this, it is possible to form the first layer 81 in which the second platinum layer 81b, which has compression stress, is stacked on the first platinum layer 81a, which has tensile stress. Since the stresses are also alleviated in the first layer 81 of this type, it is possible to suppress peeling from the piezoelectric body layer 70.

In addition, the sputtering device is not particularly limited as long as it has a configuration or method that can form a platinum layer. For example, it is possible to use a sputtering device that uses a pole-pole array, a magnetron sputtering technique, or the like. In addition, the film thicknesses of the first platinum layer 81a and the second platinum layer 81b are not particularly limited to the above-mentioned 2.5 nm. It is not necessary for the first platinum layer 81a and the second platinum layer 81b to have the same film thickness, and it is possible to adjust the film thicknesses of the first platinum layer 81a and the second platinum layer 81b using the stresses. For example, when the size of the absolute value of the compression stress of the first platinum layer 81a is greater than the size of the absolute value of the tensile stress of the second platinum layer 81b, it is possible to suppress peeling by making the thickness of the first platinum layer 81a less than the thickness of the second platinum layer 81b. Furthermore, as long as the sputtering power that is applied to the first platinum layer 81a is higher than the sputtering power that is applied to the second platinum layer 81b, the other film formation conditions are not particularly limited.

Although not specifically illustrated in the drawings, a titanium layer, which is formed from titanium (Ti), may be formed on the first layer 81, that is, on the second platinum layer 81b, and heat treatment may be carried out thereafter. The titanium layer can be formed using a sputtering technique, and, for example, it is preferable that the film thickness thereof be approximately 2.5 nm. For example, the heat treatment is carried out in an oxygen atmosphere at 700° C. for 5 minutes.

As a result of providing a titanium layer on the first layer 81, which is formed from platinum, and carrying out the heat treatment, excess lead, which is included in the piezoelectric body layer 70, is absorbed into the titanium through the first layer 81. As a result of this, the piezoelectric element 300 that is highly reliable is supplied. Additionally, the heat treatment need not necessarily be implemented. In this case, the titanium layer functions as an adhesive layer of the first layer 81 and the second layer 82, and the piezoelectric element 300 that is highly reliable is provided.

Next, as shown in FIG. 13, the first layer 81 and the piezoelectric body layer 70 are patterned to correspond to each pressure generation chamber 12. In the present embodiment, a mask (not illustrated in the drawing), which is formed in a predetermined shape, is provided on the first layer 81, and the first layer 81 and the piezoelectric body layer 70 are patterned by etching, performing so-called photolithography, thereof through the mask. Additionally, examples of the patterning of the piezoelectric body layer 70 include dry etching such as reactive ion etching and ion milling.

Next, as shown in FIG. 14, the second electrode 80 is formed by forming the second layer 82 throughout the entirety of one surface side (a surface side on which the piezoelectric body layer 70 is formed) of the flow channel formation substrate wafer 110, that is, on the first layer 81, on the side surfaces on which the piezoelectric body layer 70 is patterned, on the insulating body film 52, on the first electrodes 60, and the like.

It is preferable that the second layer 82 be a metal having a strong adhesive force with respect to platinum and the piezoelectric body layer. More specifically, it is preferable that at least one metal selected from the group consisting of iridium, nickel, tungsten, aluminum, nichrome, gold and titanium, be used. In the present embodiment, an iridium layer is formed on the above-mentioned titanium layer on the first layer 81, and a multi-layer electrode, which is formed from a titanium layer and an iridium layer, is formed as the second layer 82. As a result of using such metals, and forming the second layer 82 that covers the first layer 81, which is formed from platinum, and the side surfaces of the piezoelectric body layer 70, it is possible to reliably cause the first layer 81 and the piezoelectric body layer 70 to adhere to one another.

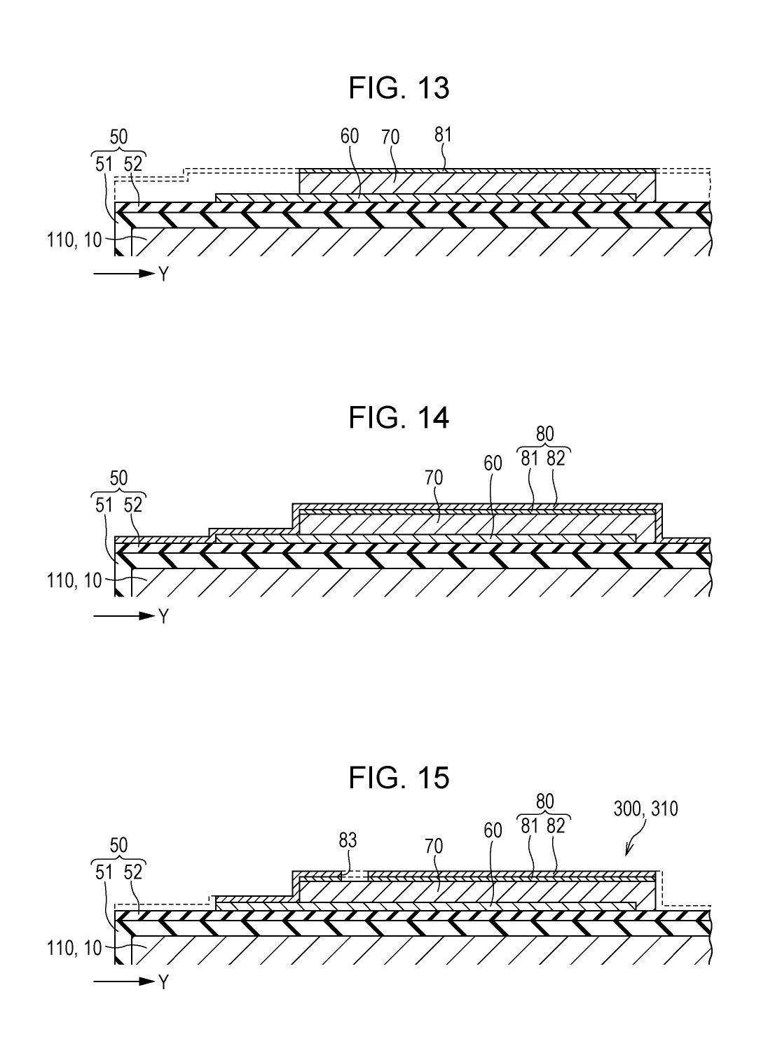

Next, as shown in FIG. 15, the second electrode 80 is patterned in a predetermined shape. As a result of this, the removed section 83, and the like, are formed.

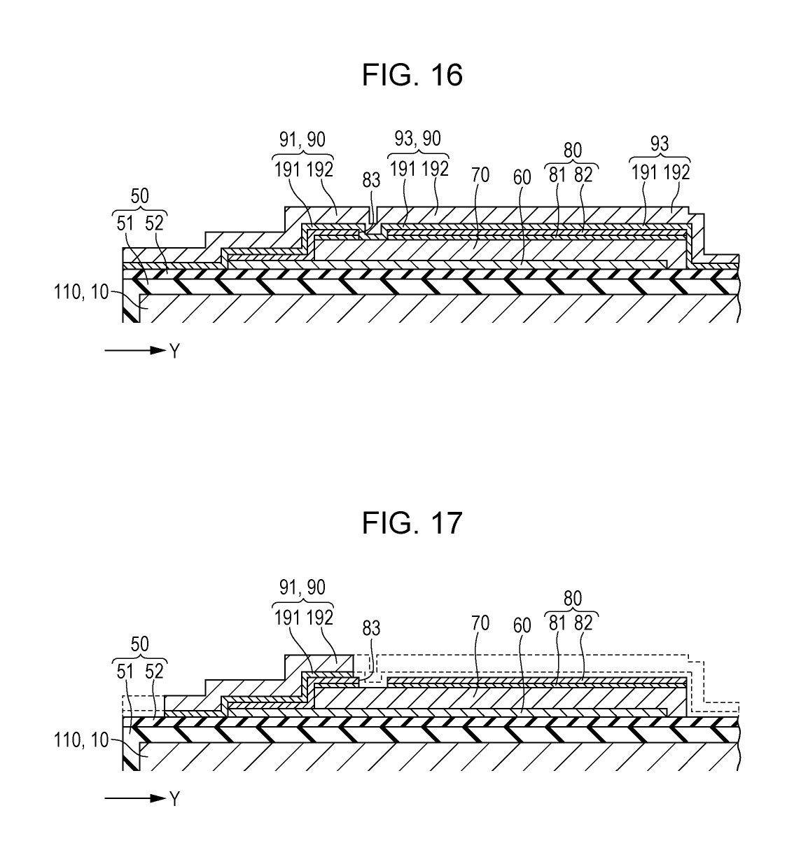

Next, as shown in FIG. 16, the lead electrode 90 is formed throughout the entirety of one surface of the flow channel formation substrate wafer 110. In the present embodiment, the lead electrode 90 is formed by stacking the adhesive layer 191 and the conductive layer 192.

Next, as shown in FIG. 17, the lead electrode 90 is patterned in a predetermined shape. In the patterning of the lead electrode 90, patterning may be performed by performing wet etching of the adhesive layer 191 after initially patterning the conductive layer 192 using wet etching or the like.

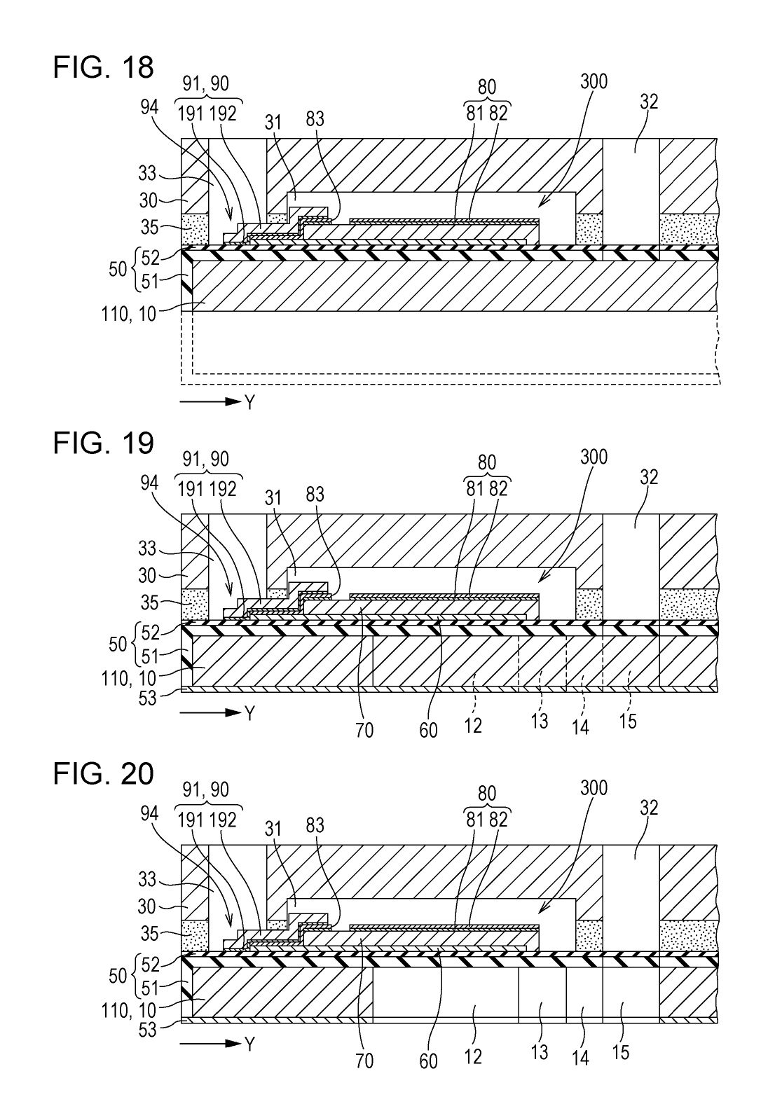

Next, as shown in FIG. 18, the flow channel formation substrate wafer 110 is thinned to a predetermined thickness after a protective substrate wafer 130, which is a silicon wafer and forms a plurality of the protective substrates 30, is joined to the piezoelectric element 300 side of the flow channel formation substrate wafer 110 using the adhesive 35.

Next, as shown in FIG. 19, a mask film 53 is newly formed on the flow channel formation substrate wafer 110, and patterning is performed in a predetermined shape. Further, as shown in FIG. 20, the pressure generation chambers 12, which correspond to the piezoelectric element 300, the ink supply channels 13, the communication channels 14 and the communication section 15 are formed by performing anisotropic etching (wet etching) of the flow channel formation substrate wafer 110 using an alkaline solution such as a KOH via the mask film 53.

Subsequently, unnecessary portions of the outer peripheral edge portions of the flow channel formation substrate wafer 110 and the protective substrate wafer 130 are removed by cutting using dicing or the like, for example. Further, in addition to joining the nozzle plate 20, in which the nozzle openings 21 are machined, to a surface on a side of the flow channel formation substrate wafer 110 that is opposite to the protective substrate wafer 130, the compliance substrate 40 is joined to the protective substrate wafer 130, and the ink jet type recording head of the present embodiment is formed by dividing the flow channel formation substrate wafer 110, and the like, into the flow channel formation substrates 10, and the like, with a single chip size such as that shown in FIG. 1.

According to the method of manufacturing a piezoelectric element of the present embodiment mentioned above, it is possible to manufacture the piezoelectric element 300 having high reliability in which a leakage current is suppressed and fracturing is prevented by using the first layer 81, which is formed from the first platinum layer 81a and the second platinum layer 81b. Further, it is possible to form the first layer 81 in which peeling and fracturing are suppressed as a result of stress being alleviated by forming, using a sputtering technique, the first platinum layer 81a with a relatively high sputtering power and the second platinum layer 81b with a relatively low sputtering power, and therefore, it is possible to manufacture the piezoelectric element 300 having high reliability.

### OTHER EMBODIMENTS

An embodiment of the invention is described above, but the basic configuration of the invention is not limited to the configurations mentioned above.

For example, in Embodiment 1 mentioned above, a configuration in which the piezoelectric body layer 70 of each of the active sections 310 is provided continuously is illustrated by way of example, but naturally, the piezoelectric body layer 70 may be provided independently for each active section 310.

The first layer 81 of the second electrode 80 is a layer in which one layer of the first platinum layer 81a and one layer of the second platinum layer 81b are stacked, but the first layer 81 is not limited to this configuration. A plurality of layers of each of the first platinum layer 81a and the second platinum layer 81b may be stacked.

The second layer 82 is formed so as to cover the first layer 81 and the side surfaces of the piezoelectric body layer 70, but the second layer 82 is not limited to this configuration, and may be formed so as to cover the first layer 81. In addition, the second layer 82 is not an essential configuration, and the second electrode 80, which is formed from the first layer 81 only, may be formed.

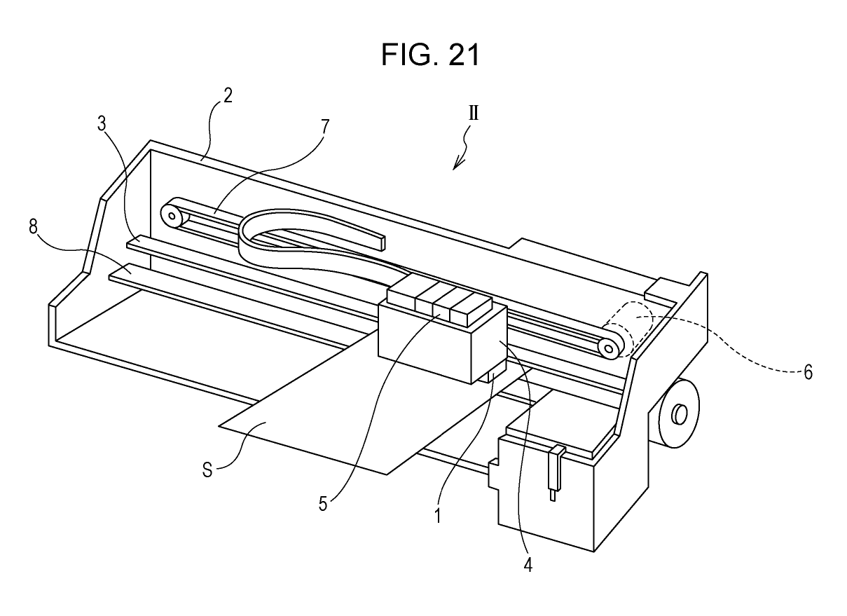

In addition, as shown in FIG. 21, the ink jet type recording head I is installed in an ink jet type recording apparatus II.

FIG. 21 is a schematic perspective view that shows an example of an ink jet type recording apparatus. The ink jet type recording apparatus II according to the present embodiment is provided with an apparatus main body 2, and a carriage shaft 3, which extends in one direction, is provided in the apparatus main body 2. A carriage 4, which is capable of reciprocating along an axial direction, is attached to the carriage shaft 3. The head 1 and ink cartridges 5 are mounted in the carriage 4.

A driving motor 6 and a timing belt 7 are provided in the apparatus main body 2. The timing belt 7 is attached to the driving motor 6 and the carriage 4, and a driving force of the driving motor 6 is transmitted to the carriage 4 via the timing belt 7. The carriage 4 reciprocates along the carriage shaft 3 as a result of driving of the driving motor 6.

Meanwhile, a platen 8 is provided along the carriage shaft 3 in the apparatus main body 2. A recording sheet S, which is a target recording medium such as paper that is supplied by a paper feeding roller (not illustrated in the drawing), or the like, is wound around the platen 8, and is transported in a direction that is orthogonal to the carriage shaft 3. Additionally, a transport unit that transports the recording sheet S is not limited to a paper feeding roller, and may be a belt, a drum or the like.

In this kind of ink jet type recording apparatus II, printing is performed on the recording sheet S as a result of the carriage 4 being moved along the carriage shaft 3, and an ink being discharged by the head 1.

Additionally, in the above-mentioned example, an apparatus in which the ink jet type recording head I is mounted in the carriage 4 and moves in a main scanning direction, is illustrated as the ink jet type recording apparatus II by way of example, but the configuration of the ink jet type recording apparatus II is not particularly limited. For example, the ink jet type recording apparatus II may be a so-called line-type recording apparatus in which the ink jet type recording head I is fixed, and printing is performed by moving a recording sheet S such as paper, in a sub-scanning direction.

In addition, in the above-mentioned example, the ink jet type recording apparatus II has a configuration in which ink cartridges 2A and 2B, which are liquid accumulation units, are mounted in the carriage 4, but the ink jet type recording apparatus II is not particularly limited to this configuration, and for example, a liquid accumulation unit such as an ink tank may be fixed to the apparatus main body 2, and the liquid accumulation unit and the ink jet type recording head I may be connected via a supply pipe such as a tube. In addition, a liquid accumulation unit need not necessarily be mounted on the ink jet type recording apparatus.

Additionally, in the above-mentioned embodiment, description is given using an ink jet type recording head as an example of a liquid ejecting head and an ink jet type recording apparatus as an example of a liquid ejecting apparatus, but, the invention was devised for all liquid ejecting heads and liquid ejecting apparatuses, and naturally, can also be applied to liquid ejecting heads and liquid ejecting apparatuses that eject liquids other than ink. Examples of such other liquid ejecting heads include various recording heads that are used in image recording apparatuses such as printers, color material ejecting heads that are used in the manufacture of color filters such as liquid crystal displays, electrode material ejecting heads that are used in electrode formation such as organic EL displays, Field Emission Displays (FEDs) and the like, living organic material ejecting heads that are used in the production of biochips and the like, and it is also possible to apply the invention to liquid ejecting apparatuses that are provided with such liquid ejecting heads.

In addition, the piezoelectric element of the invention is not limited to a piezoelectric actuator that is installed in a liquid ejecting head, of which an ink jet type recording head is representative, and can be applied to other piezoelectric devices such as ultrasonic wave devices such as ultrasonic wave transmitters, ultrasonic wave motors, pressure sensors, pyroelectric sensors, and the like.

The entire disclosure of Japanese Patent Application No. 2015-177846, filed Sep. 9, 2015 is expressly incorporated by reference herein in its entirety.

What is claimed is:

1. A method of manufacturing a piezoelectric element, which is provided with first electrodes, a piezoelectric body layer, and a second electrode including a first platinum layer and a second platinum layer, in which the first electrodes are individual electrodes that are respectively provided in an electrically independent manner for active sections, and in which the second electrode is a common electrode that is provided in an electrically common manner throughout the active sections, the method comprising:
forming the first platinum layer having compression stress or tensile stress on the piezoelectric body layer, which is provided on the first electrodes, using a sputtering technique; and
forming the second platinum layer having tensile stress or compression stress, on the first platinum layer using a sputtering technique with a sputtering power that differs from that during formation of the first platinum layer.

2. The method of manufacturing a piezoelectric element according to claim 1, further comprising:
forming the first platinum layer having compression stress, on the piezoelectric body layer, using a sputtering technique; and
forming the second platinum layer having tensile stress, on the first platinum layer using a sputtering technique with a lower sputtering power than that during formation of the first platinum layer.

3. The method of manufacturing a piezoelectric element according to claim 1, further comprising:
forming a titanium layer on the second platinum layer.

4. The method of manufacturing a piezoelectric element according to claim 3, further comprising:
performing a heat treatment after formation of the second platinum layer.

5. The method of manufacturing a piezoelectric element according to claim 1,
wherein the second electrode includes a second layer that is provided on a first layer formed from the first platinum layer and the second platinum layer, and
the second layer, which covers an outer surface of the first layer and a side surface of the piezoelectric body layer, is formed.

6. The method of manufacturing a piezoelectric element according to claim 5,
wherein the second layer, which includes at least one metal selected from a group consisting of iridium, nickel, tungsten, aluminum, nichrome, gold and titanium, is formed.
